(19) United States
(12) Patent Application Publication
(10) Pub. No.: US 2012/0020153 A1
(43) Pub. Date: Jan. 26, 2012

(54) Nonvolatile Memory Devices with Highly Reliable Programming Capability and Methods of Operating Same

(76) Inventor: Sang-hyun Joo, Hwaseong-si (KR)

(21) Appl. No.: 13/180,730

(22) Filed: Jul. 12, 2011

(30) Foreign Application Priority Data
Jul. 22, 2010 (KR) 10-2010-0071060

(51) Int. Cl. G11C 16/10; G11C 16/04; G11C 16/06

(52) U.S. Cl. 365/185.03; 365/185.2; 365/185.25

(57) ABSTRACT

Programming methods of a non-volatile memory device by which a programming error is less likely to occur. A programming method may involve applying a precharge voltage to a program inhibit cell at a different time according to the threshold voltage of the program inhibit cell. A programming method may involve applying a different level of precharge voltage to a program inhibit cell according to the threshold voltage of the program inhibit cell.

### REFERENCE TO PRIORITY APPLICATION

This application claims priority to and the benefit of Korean Patent Application No. 10-2010-0071060, filed on Jul. 22, 2010, in the Korean Intellectual Property Office, the entire contents of which are hereby incorporated herein by reference.

### BACKGROUND

In developing semiconductor memory devices, one of the main issues is to maximize the data storage capacity indicating the number of data bits storable per unit area. Accordingly, there has been an increased demand for memory chips capable of storing the largest amount of data as possible in the smallest area as possible.

Flash memory devices, which is a kind of non-volatile memory device, program and erase data via tunneling. Flash memory devices have good data retention ability with low-power consumption features and are very strong against external impact, and thus are suitable as auxiliary memory devices of portable devices. An NAND flash memory device, which includes a certain number of serially connected memory cells, is smaller in cell size as compared to a NOR flash memory device, which includes memory cells connected in parallel, and has a high integration density, and thus is useful as a large-capacity auxiliary memory device. The NAND flash memory device uses multi-level cells (MLCs), each including multiple bits of data, for a larger amount of data storage.

### SUMMARY

The inventive concept provides a programming method by which increment step pulse programming (ISPP) errors are less likely to occur in a programming of a memory cell.

The inventive concept provides a non-volatile memory device that executes the programming method.

The inventive concept provides a memory system including the non-volatile memory device.

According to an aspect of the inventive concept, there is provided a programming method of a non-volatile memory device, the method including: applying a precharge voltage to a bit line of a first program inhibit cell; sequentially applying a first pass voltage, a second pass voltage, and a programming voltage to a word line of a programming memory cell; and applying the precharge voltage to a bit line of a second program inhibit cell before the second pass voltage is applied to the word line of the programming memory cell.

According to another aspect of the inventive concept, there is provided a programming method of a non-volatile memory device, the method including: applying a first precharge voltage to a bit line of a first program inhibit cell; applying a second precharge voltage to a bit line of a second program inhibit cell; and applying a programming voltage of a word line of a programming memory cell.

According to another aspect of the inventive concept, there is provided a non-volatile memory device including: a multi-level memory cell to which a first pass voltage, a second pass voltage, and a programming voltage are sequentially applied via a corresponding word line in a programming operation; and a read/write circuit unit which applies a precharge voltage of a bit line of a program inhibit cell having the highest threshold voltage before the second pass voltage is applied to the word line.

According to another aspect of the inventive concept, there is provided a non-volatile memory device including: a multi-level memory cell to which a programming voltage is applied to a corresponding word line in a programming operation; and a read/write circuit unit that applies a first precharge voltage to a bit line of a first program inhibit cell and a second precharge voltage to a bit line of a second program inhibit cell before the programming voltage is applied to the word line.

According to another aspect of the inventive concept, there is provided a memory system including: a non-volatile memory device; and a controller for controlling the non-volatile memory device, wherein the non-volatile memory device includes: a multi-level memory cell to which a first pass voltage, a second pass voltage, and a programming voltage are sequentially applied via a corresponding word line in a programming operation; and a read/write circuit unit which applies a precharge voltage of a bit line of a program inhibit cell having the highest threshold voltage before the second pass voltage is applied to the word line.

According to another aspect of the inventive concept, there is provided a memory system including: a non-volatile memory device; and a controller for controlling the non-volatile memory device, wherein the non-volatile memory device includes: a multi-level memory cell to which a programming voltage is applied to a corresponding word line in a programming operation; and a read/write circuit unit that applies a first precharge voltage to a bit line of a first program inhibit cell and a second precharge voltage to a bit line of a second program inhibit cell before the programming voltage is applied to the word line, the second precharge voltage being higher than the first precharge voltage.

In some embodiments the non-volatile memory device and the controller in each of the memory systems described above may constitute a semiconductor disk device.

In some embodiments the non-volatile memory device and the controller in each of the memory systems described above may constitute a memory card.

### BRIEF DESCRIPTION OF THE DRAWINGS

Exemplary embodiments of the inventive concept will be more clearly understood from the following detailed description taken in conjunction with the accompanying drawings in which:

FIG. 1 illustrates the relationship between memory cell data and threshold voltages of multi-level cells (MLC);

FIG. 2 is a diagram for describing a programming operation of a MLC memory cell;

FIG. 3 is a diagram for describing a programming operation of a MLC memory cell;

FIG. 4 is a graph for describing an increment step pulse programming (ISPP) method;

FIG. 5 illustrates an embodiment of a non-volatile memory device that operates at least one programming operation according to embodiments;

FIG. 6 is a timing diagram for describing an embodiment of a programming method of the non-volatile memory device of FIG. 5;

FIG. 7 is a cross-sectional view of memory cells MT0-MT2 along a line I-II of FIG. 5;

FIG. 8 is a timing diagram for describing another embodiment of a programming method of the non-volatile memory device of FIG. 5;

FIG. 9 illustrates a memory system including at least one non-volatile memory device that is programmed according to at least one embodiment of the programming method;

FIG. 10 illustrates a memory module including at least one non-volatile memory device that is programmed according to at least one embodiment of the programming method; and

FIG. 11 illustrates a computer system including the memory system of FIG. 9 or the memory module of FIG. 10.

### DETAILED DESCRIPTION OF THE EMBODIMENTS

The present invention will now be described more fully with reference to the accompanying drawings, in which exemplary embodiments of the invention are shown. In the drawing like reference numerals refer to like elements.

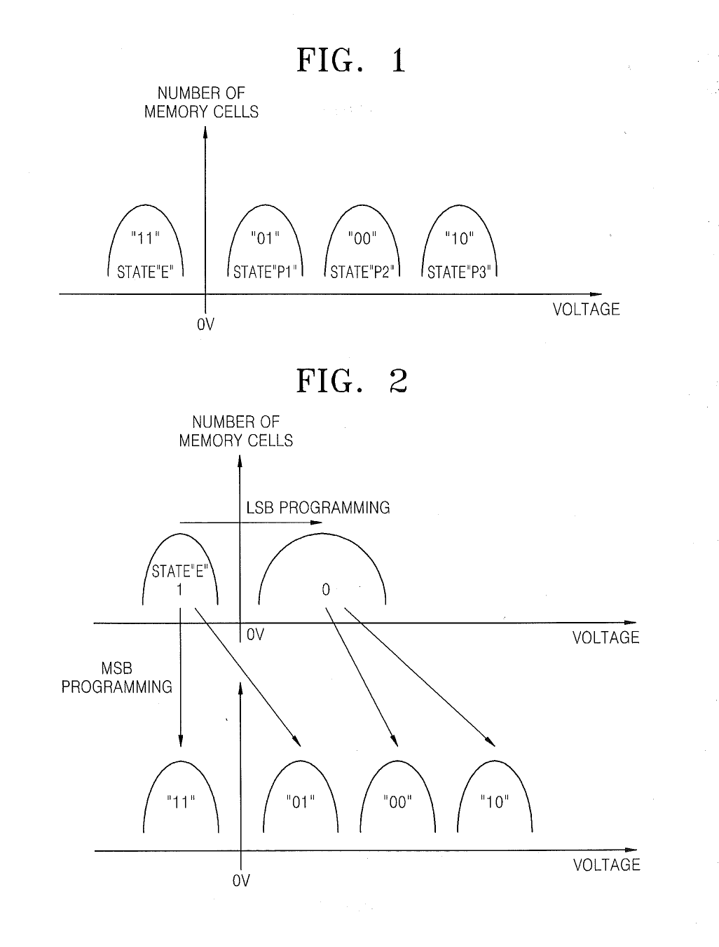

FIG. 1 illustrates the relationship between memory cell data and threshold voltages of memory cells. The memory cells of the current embodiments are multi-level cells (MLC). Referring to FIG. 1, states “E”, “P1”, “P2”, and “P3” of data of the memory cells indicate threshold voltages from lowest to highest, respectively. The state of data of the memory cells becomes “E” by an erasing operation and shifts to a state with a higher threshold voltage by a programming operation. If a memory cell stores 2 bits of data, the 2 bits of data include most significant bit (MSB) data and least significant bit (LSB) data.

One memory cell stores one type of data among four types of data expressed with 2 bits, (i.e., 11, 01, 00, and 10), and a threshold voltage level of the memory cell varies depending on the type of stored data. A threshold voltage of a memory cell storing a first type of data, (i.e., 11), corresponding to the erase state “E” is lower than 0V. Second to fourth types of data, (i.e., 01, 00, and 10), are stored in memory cells by a programming operation, and threshold voltages of these memory cells are higher than 0V. In order to vary the threshold voltage of memory cells according to the stored data, a LSB programming operation and a MSB programming operation are executed.

FIG. 2 is a diagram for describing a programming operation of a memory cell (MLC). Referring to FIG. 2, a lateral arrow indicates a LSB programming operation, and downward arrows indicate MSB programming operations. LSB programming operations are executed in order to increase threshold voltages of the memory cells to store one of the third and fourth types of data (00, 10) among the memory cells of the state E storing the first type of data (11) via an erasing operation, to be higher than 0V.

MSB programming operations are executed in order to increase threshold voltages of the memory cells (hereinafter, “second memory cells”) to store the second type of data (01) among the memory cells in the state “E” storing the first type of data 11 via the erasing operation, to a first level that is higher than 0V. MSB programming operations may also be executed in order to increase threshold voltages of the memory cells (hereinafter, “third memory cells”) to store the third type of data (00) among the memory cells that have undergone LSB programming operations, to a second level that is higher than the first level. MSB programming operations may also be executed in order to increase threshold voltages of the memory cells (hereinafter, “fourth memory cells”) to store the fourth type of data (10) among the memory cells having undergone LSB programming operations, to a third level that is higher than the second level. At least two MSB programming operations may be executed to store each of the second to fourth types of data (10, 00, 10).

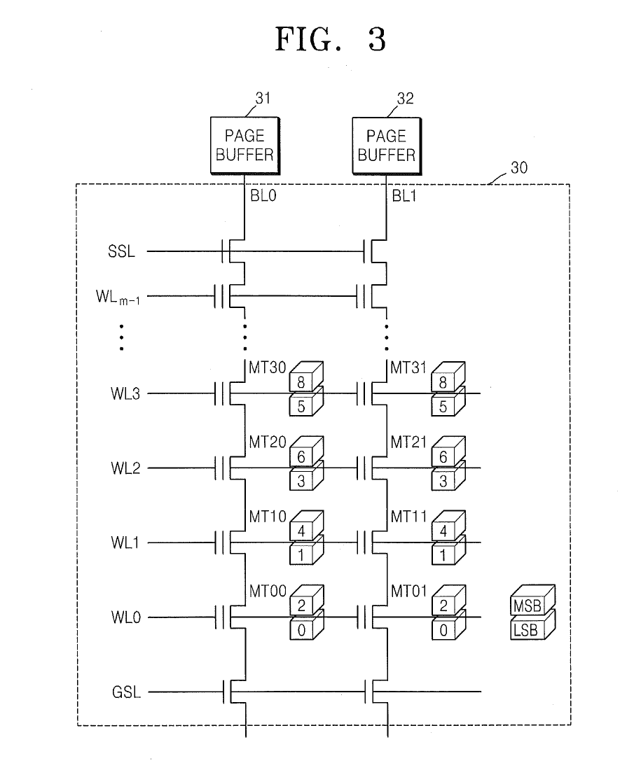

FIG. 3 is a diagram for describing a programming operation of a MLC memory cell. Referring to FIG. 3, figures in LSB and MSB regions of the memory cells MT00-MT30 and MT01-MT31 indicate the order in which programming operations are executed. A bit line BL0 connected to a string in which the memory cells MT00-MT30 are coupled and a bit line BL1 connected to a string in which the memory cells MT01-MT31 are coupled are respectively coupled to corresponding page buffers 31 and 32. The structure in which a page buffer is connected to each bit line BL0 and BL1 is referred to as “All Bit Line (ABL)” structure.

In the ABL structure LSB programming operations are executed on the memory cells MT00 and MT01 that share a first word line WL0. Subsequently, LSB programming operations are executed on the memory cells MT10 and MT11 that share a second word line WL1. Then, after MSB programming operations are executed on the memory cells MT00 and MT01, which share the first word line WL0, LSB programming operations are executed on the memory cells MT20 and MT21 that share a third word line WL2. Then, after MSB programming operations are executed on the memory cells MT10 and MT11, which share the second word line WL1, LSB programming operations are executed on the memory cells MT30 and MT31 that share a fourth word line WL3. Then, after MSB programming operations are executed on the memory cells MT20 and MT21, which share the third word line WL2, MSB programming operations are executed on the memory cells MT30 and MT3, which share the fourth word line WL3.

That is to say, programming operations on MLC memory cells are executed in the order of a MSB programming operation on the memory cells connected to a selected work line (e.g., WL1) after an LSB programming operation on the memory cells connected to a next word line (e.g., WL2). If MSB programming operations on the memory cells that share a word line WLm-1 adjacent to a string selection line SSL is completed according to the programming operation order, the programming operations on all the memory cells in a memory cell block 30 are completed.

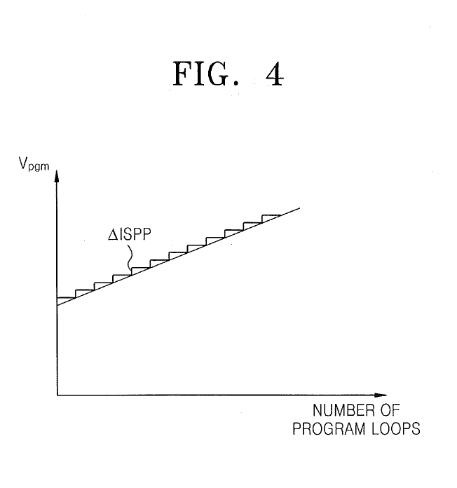

For accurate control of threshold voltage distribution of MLC memory cells as in FIG. 1, an increment step pulse programming (ISPP) method is used. According to the ISPP method, a programming voltage Vpgm is stepwise increased with an increasing number of loops in a programming cycle, as illustrated in FIG. 4. The programming voltage Vpgm is increased by a certain increment (ΔISPP). While the programming operation is executed, the threshold voltage of a cell to be programmed is increased by the increment (ΔISPP) defined in each programming loop. For this reason, the increment (ΔISPP) of the programming voltage should be defined to be small in order to narrow the threshold voltage distribution of the final programmed cell.

A memory cell to store the first type of data (11), which corresponds to the erase state “E”, may not be programmed by the LSB programming operation or MSB programming operation. As such, those memory cells are referred to as “program inhibit cells” which should maintain stored data without changes even when programming operations are executed. The LSB programming operation or MSB programming operation is executed in a state where a channel voltage of a program inhibit cell is boosted (or precharged) by a precharge voltage (e.g., a power voltage VDD) applied to a bit line that is connected to the program inhibit cell.

A boosted channel voltage of the program inhibit cell may cause a rise in potential of floating gates of a string of memory cells that are to be programmed and are adjacent to the program inhibit cell. Thus, a threshold voltage increment (ΔVt) of the memory cells to be programmed may be larger than the increment (ΔISPP) of the programming voltage (Vpgm). This incidence is called an “ISPP error”. ISPP errors may induce an insufficient read margin to programmed memory cells, since the threshold voltage (ΔVt) of the programming memory cell is increased in a program inhibit loop during which a program inhibit cell adjacent to a programming memory cell is inhibited, and thus the threshold voltage distribution of the programming memory cell becomes wide.

The larger the boosted channel voltage of the program inhibit cell, the higher the potential of a floating gate of the programming memory cell, and thus the larger the ISPP error. Thus, if the channel voltage of the program inhibit cell is boosted less, the ISPP error may be less likely to occur.

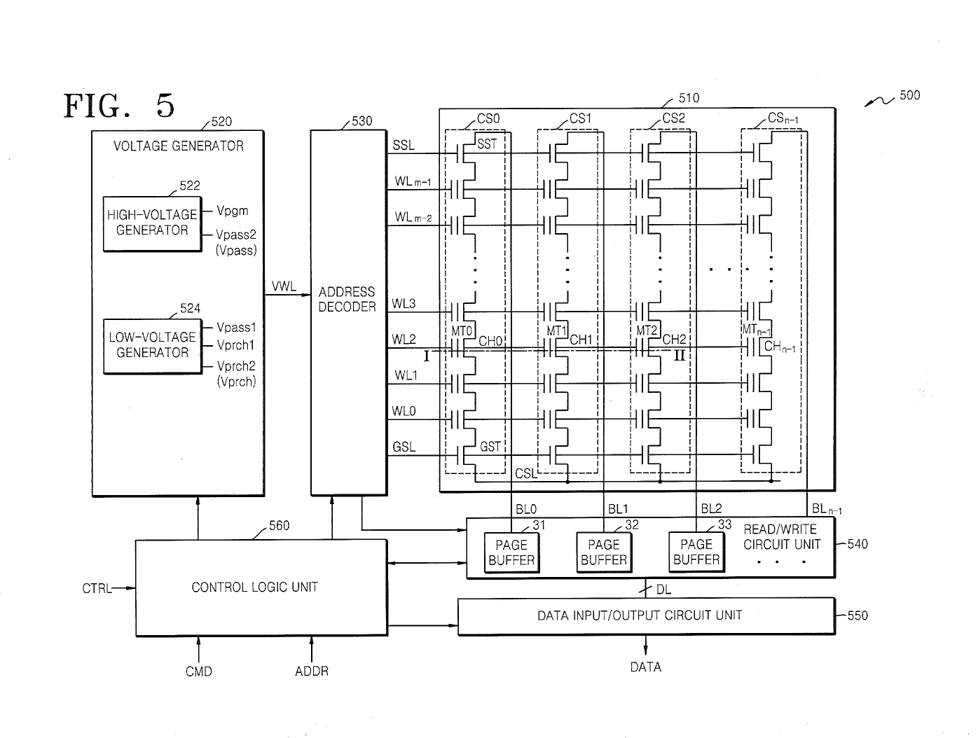

FIG. 5 illustrates an embodiment of a non-volatile memory device 500 that operates according to at least one programming operation according to embodiments. Referring to FIG. 5, the non-volatile memory device 500 includes a memory cell array 510, a voltage generator 520, an address decoder 530, a read/write circuit unit 540, a data input/output circuit unit 550, and a control logic unit 560. The memory cell array 510 is connected to the address decoder 530 via a string selection line SSL, word lines WL0-WLm-1, and a ground selection line GSL, and is connected to the read/write circuit unit 540 via bit lines BL0-BLn-1. The memory cell array 510 includes a plurality of MLC memory cells, wherein memory strings CS0-CSn-1 of the MLC memory cells are serially connected between the bit lines BL0-BLn-1 and a common source line CSL. The memory strings CS0-CSn-1, which are arranged in columns, constitute the memory cell array 510. The non-volatile memory device 500 may include a plurality of memory cell arrays 510. However, for convenience of explanation the present embodiment is described as that the non-volatile memory device 500 includes one memory cell array 510. One memory cell array 510 constitutes one block, and the operation of erasing memory cell data is executed in units of blocks.

The memory cell array 510 includes the memory strings CS0-CSn-1 respectively connected to n bit lines BL0-BLn-1. The memory strings CS0-CSn-1 are commonly connected to the common source line CSL. Gates of the memory cells of the memory string CS0 are respectively coupled to the word lines WL0-WLm-1. Gates of string selection transistors SST, which respectively connect the corresponding memory strings CS0-CSn-1 to the bit lines BL0-BLn-1, are coupled to the string selection line SSL. Gates of ground selection transistors GST, which respectively connect the corresponding memory strings CS0-CSn-1 to the common source line CSL, are coupled to the ground selection line GSL.

The voltage generator 520 includes a high-voltage generator 522 and a low-voltage generator 524, which perform charge pumping and voltage regulating operations by using a power voltage VDD according to a pumping clock signal received from the control logic unit 560. The high-voltage generator 522 generates a programming voltage Vpgm and a second pass voltage Vpass2 and provides the same as a word line driving voltage VWL. The programming voltage Vpgm may have a voltage level of about 15V to about 20V. The second pass voltage Vpass2 may have a voltage level of about 7V to about 10V. The low-voltage generator 524 generates a first pass voltage Vpass1 and precharge voltages Vprch1, Vprch2, and Vprch and provides the same as a word line driving voltage VWL. The first pass voltage Vpass1 may have a voltage level of about 3.5V to about 5V. The first precharge voltage Vprch1 may have a voltage level of about 1.0V, which is lower than a power voltage VDD of about 2.5V. The second precharge voltage Vprch2 may have a voltage level substantially equal to the level of the power voltage VDD. The precharge voltage Vprch may have a voltage level substantially equal to the level of the power voltage VDD.

The address decoder 530 is connected to the memory cell array 510, the read/write circuit unit 540, and the control logic unit 560. The address decoder 530 decodes address signals ADDR received from the control logic unit 560 to selectively activate the string selection line SSL, the ground selection line GSL, the word lines WL0-WLm-1, and the bit lines BL0-BLn-1 connected to the memory cell array 510. The address decoder 530 decodes row addresses among the addresses ADDR to select word lines WL0-WLm-1. The address decoder 530 decodes column addresses among the addresses ADDR to provide the same to the read/write circuit unit 540. For example, the address decoder 530 may include a row decoder, a column decoder, and an address buffer. The address decoder 530 transfers the word line driving voltage VWL generated by the voltage generator 520 to the string selection line SSL, the ground selection line GSL, and the word lines WL0-WLm-1.

The read/write circuit unit 540 is connected to the memory cell array 510, the address decoder 530, the control logic unit 560, and the data input/output circuit unit 550. The read/write circuit unit 540 operates in response to the control of the control logic unit 560. The read/write circuit unit 540 selects the bit lines BL0-BLn-1 in response to a column address decoded by the address decoder 530. The read/write circuit unit 540 writes data transferred from the data input/output circuit unit 550 via a data line DL to selected memory cells. The read/write circuit unit 540 reads the data stored in the selected memory cell and transfers the data to the data input/output circuit unit 550 via the data line DL. The read/write circuit unit 540 may include a column selection circuit and page buffers 31-33 respectively coupled to the bit lines BL0-BLn-1. Alternatively, the read/write circuit unit 540 may include a column selection circuit, a write driver, and a sense amplifier.

The data input/output circuit unit 550 is connected to the logic control unit 560 and the read/write circuit unit 540. The data input/output circuit unit 550 operates in response to the control of the control logic unit 560. The data input/output circuit unit 550 exchanges data with external devices. The data input/output circuit unit 550 transfers externally received data DATA to the read/write circuit unit 540. The data input/output circuit unit 550 externally transfers data DATA received from the read/write circuit unit 540. The data input/output circuit unit 550 may include, for example, a data buffer. The control logic unit 560 is connected to the voltage generator 520, the read/write circuit unit 540, and the data input/output circuit unit 550. The control logic unit 560 receives an address signal ADDR, a command signal CMD and a control signal CTRL to control the overall operation of the non-volatile memory device 500.

As described above, in order to make the channel voltage of a program inhibit cell boosted less to suppress an ISPP error, the control logic unit 560 may control programming operations by varying the timing at which a precharge voltage is applied, according to the threshold voltage of the program inhibit cell. The control logic unit 560 may control programming operations by varying the level of the precharge voltage to be applied to the program inhibit cell, according to the threshold voltage of the program inhibit cell. Programming operations are controlled by the control logic unit 560 and are executed by the read/write circuit unit 540 that applies the precharge voltages Vprch1, Vprch2, and Vprch generated by the voltage generator 520 to the program inhibit cell.

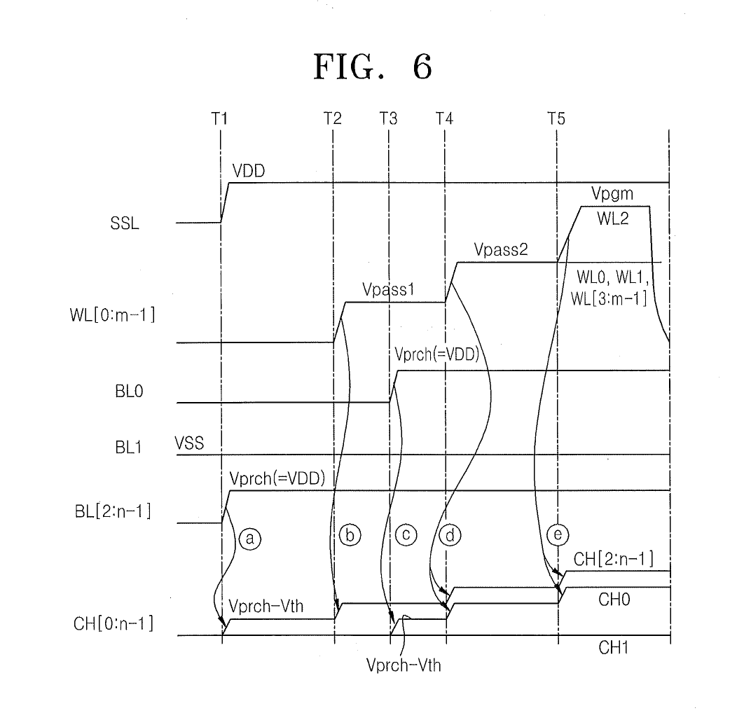

FIG. 6 is a timing diagram for describing an embodiment of a programming method of the non-volatile memory device 500 of FIG. 5. It is assumed that the memory cell MT1 among the memory cells MT0-MTn-1 in the memory cell array 510 of FIG. 5 is a programming cell to be programmed, and the rest of the memory cells MT0 and MT2-MTn-1 are program inhibit cells. As an example, it is also assumed that the memory cell MT0 among the program inhibit memory cells MT0 and MT2-MTn-1 is to be programmed or has been programmed with the fourth type of data (10) of the state “P3” of FIG. 1, and the rest of the program inhibit memory cells MT2-MTn-1 are to be programmed or have been programmed to a state, which is not the state “P3”.

Referring to FIG. 6, in conjunction with FIG. 5, the data input/output circuit unit 550 receives data DATA from an external device. The received data DATA is provided to the read/write circuit unit 540 via the data line DL. The received data DATA includes LSB data and MSB data to be stored in MLC memory cells. The MSB data is received after the LSB data is received. The page buffers 31, 32, 33, and the like of the read/write circuit unit 540 perform a programming operation on the memory cells MT0-MTn-1 with the received data DATA, according to LBS programming operations for the MLC memory cells. Then, prior to programming the memory cells MT0-MTn-1 with the received MSB data according to MSB programming operations for the MLC memory cells, the LSB data stored in the memory cells MT0-MTn-1 is read. Based on the read LSB data, the received MSB data is programmed on the memory cells MT0-MTn-1.

A programming operation on the memory cell MT1 will now be described. The page buffers 31, 32, 33, and the like perform LSB programming operations on the memory cells MT0-MTn-1, respectively, based on the received LSB data. Corresponding LSB data is programmed on the memory cell MT1. The LSB programming operation is not immediately followed by a MSB programming operation on the memory cell MT1. Prior to the MSB programming operation on the memory cell MT1, the page buffers 31, 32, 33 and the like read the LSB data programmed on the respective memory cells MT0-MTn-1 and latch the same. The page buffers 31, 32, 33, and the like may be aware of which of the memory cells MT0-MTn-1 is to be programmed with the fourth type of data (10) of the state “P3”, based on the latched LSB data and the received MSB data and the currently received MSB data. The page buffers 31, 32, 33, and the like may be aware that the memory cells MT2-MTn-1 are to be programmed to a state, which is not the state “P3”.

If a memory cell, for example, the memory cell MT0, programmed before the memory cell MT1, which is to be programmed, has completely been programmed with the fourth type of data (10) of the state “P3”, the page buffers 31, 32, 33, and the like may be aware of the fact that the memory cell MT0 has been programmed with the fourth type of data (10) of the state “P3”. If the memory cells, for example, the memory cells MT2-MTn-1, programmed before the memory cell MT1, which is to be programmed, have been completely programmed with data to a state, which is not the state “P3”, the page buffers 31, 32, 33, and the like may be aware of the fact that the memory cells MT2-MTn-1 memory cells have been programmed to a state, which is not the state “P3”.

That is to say, before the MSB operation on the memory cell MT1, the page buffers 31, 32, 33, and the like may be aware that the memory cell MT0 is to be programmed or has been programmed with the fourth type of data (10) of the state “P3” and the memory cells MT2-MTn-1 are to be programmed or have been programmed to a state, which is not the state “P3”. This information is transferred to the control logic unit 560 connected to the read/write circuit unit 540 including the page buffers 31, 32, 33, and the like.

The control logic unit 560 controls the non-volatile memory device 500 to execute a MSB programming operation on the memory cell MT1 according to the information about the state in which each of the memory cells MT0-MTn-1 is programmed.

A MSB programming operation is executed on the memory cell MT1 as follows. At a first bit line precharge time T1, a power voltage VDD is applied to the string selection line SSL, and the ground voltage VSS is applied to the bit line BL0 coupled to the program inhibit string CS0. The ground voltage VSS is also applied to the bit line BL1 coupled to the programming string CS1, and the power voltage VDD as a precharge voltage Vprch is applied to the bit line BL[2:n-1] coupled to the program inhibit strings CS[2:n-1]. Accordingly, the voltage of a channel CH[2:n-1] of the memory cell MT[2:n-1] is boosted by the power voltage VDD applied to the bit line BL[2:n-1], to about a voltage level (Vprch−Vth) equal to a difference between the precharge voltage Vprch and a threshold voltage (Vth) of the string selection transistor SST (1).

At a first pass voltage applying time T2, the first pass voltage Vpass1 generated by the voltage generator 530 is applied to the word lines WL[0:m-1], and the voltage level of the channel CH[2:n-1] of the memory cell MT[2:n-1] increases by being coupled with the first pass voltage Vpass1 applied to the word lines WL[0:m-1] (2).

At a second bit line precharge time T3, the power voltage VDD as a precharge voltage Vprch is applied to the bit line BL0 coupled to the program inhibit string CS0. Accordingly, the voltage of a channel CH0 of the memory cell MT0 is boosted by the precharge voltage Vprch applied to the bit line BL0, to about a voltage level (Vprch−Vth) equal to a difference between the precharge voltage Vprch and the threshold voltage (Vth) of the string selection transistor SST (3). As described above, the MSB programming operation on the memory cell MT1 is controlled in such a manner that the power voltage VDD is applied to the bit line BL0 after the first pass voltage Vpass1 has been applied to the word lines WL[0:m-1], based on the information about that the memory cell MT0 is programmed with the fourth type of data (10) of the state “P3”.

At a second pass voltage applying time T4, the second pass voltage Vpass2 generated by the voltage generator 530 is applied to the word lines WL[0:m-1]. The second pass voltage Vpass2 may have substantially the same voltage level as the pass voltage Vpass that has been applied to all the word lines (WL[0:m-1]) before a programming voltage Vpgm is applied to a selected word line WL2 in a general programming operation. The voltage levels of channels CH[2:n-1] of the memory cells MT[2:n-1] and the voltage level of the channel (CH0) of the memory cell MT0 increase by being coupled with the second pass voltage Vpass2 applied to the word lines WL[0:m-1] (4).

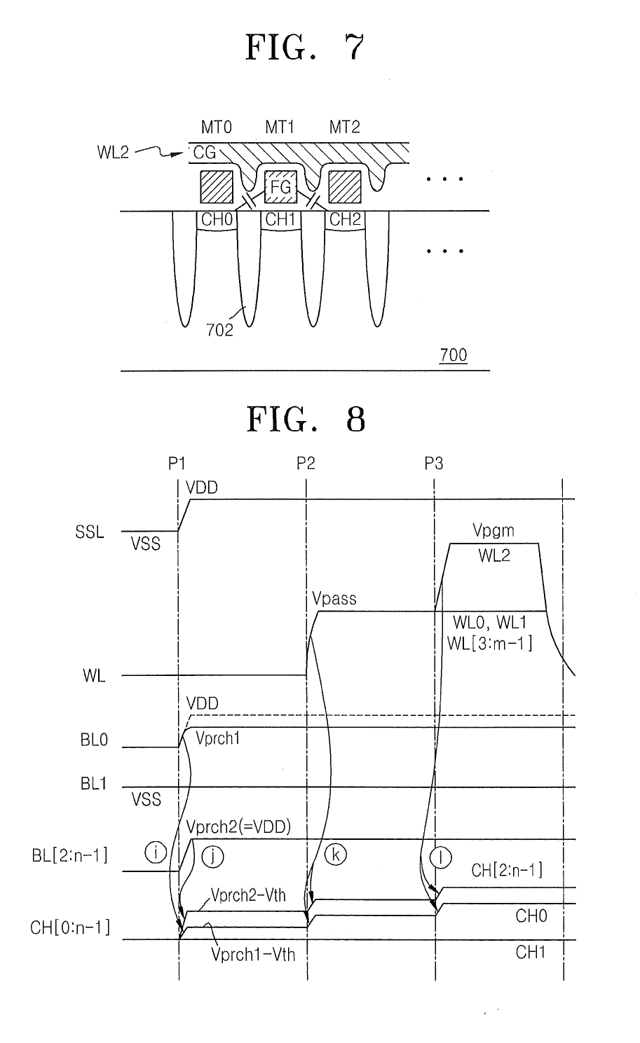

At a programming voltage applying time T5, the programming voltage Vpgm generated by the voltage generator 530 is applied to the selected word line WL2. The second pass voltage Vpass2 is applied to the rest of the word lines WL0, WL1, WL[3:m-1]). The voltage levels of the channels CH[2:n-1] of the memory cells MT[2:n-1] and the voltage level of the channel of the memory cell MT0 increase by being coupled with the programming voltage Vpgm applied to the word line WL2 (5). FIG. 7 shows impacts of the voltage of the channel CH0 of the memory cell MT0 and the voltages of the channels CH[2:n-1] of the memory cells MT[2:n-1] on the memory cell MT1 during the programming operation on the memory cell MT1.

FIG. 7 is a cross-sectional view of the memory cells MT0-MT2 along a line I-II of FIG. 5. Referring to FIG. 7, floating gates FG are disposed apart from each other on a semiconductor substrate 700, and a control gate CG is disposed on the floating gates FG. The control gate CG constitutes the word line WL2, and regions corresponding to the control gates FG constitute the memory cells MT0, MT1, and MT2, respectively. Surface regions of the semiconductor substrate 700 underlying the floating gates FG respectively constitute memory cell channels CH0, CH1, and CH2 of the respective memory cells MT0, MT1, and MT2. The memory cell channels CH0, CH1, and CH2 are separated from each other by device isolation regions 702 defined in the semiconductor substrate 700.

The voltage of the memory cell channel CH2 is boosted in proportion to the second pass voltage Vpass2. The voltage of the memory cell channel CH0 is boosted in proportion to a difference between the second pass voltage Vpass2 and the first pass voltage Vpass1, i.e., (Vpass2−Vpass1). That is to say, the voltage of the memory cell channel CH0 is lower than the voltage of the memory cell channel CH2. Thus, the voltage of the memory cell channel CH0 is less coupled to the floating gate FG of the memory cell MT1 than the voltage of the memory cell channel CH2.

In the programming method according to FIG. 6 the voltage of the memory cell channel CH0 has a less significant coupling to the floating gate FG, as compared to conventional programming methods in which the voltage of the memory cell channel CH0 is boosted, like the memory cell channel CH2, in proportion to the second pass voltage Vpass2 and is coupled to the floating gate FG of the memory cell MT1 as much as the voltage of the memory cell channel CH2. Thus, an ISPP error less likely occurs in the memory cell MT1.

Though the voltage of the memory cell channel CH1 is lowered, the memory cell MT1 is still programmed to the state “P3” in which the voltage level is equal to or higher than a validation voltage, and thus, programming on the memory cell MT1 may not be disturbed by the programming voltage Vpgm applied to the word line WL2.

After the MSB programming operation on the memory cell MT1 is completed, a programming validation operation is executed. If the programming on the memory cell MT1 is validated as “pass” in the validation operation, the programming operation is terminated. If the programming on the memory cell MT1 is validated as “failure”, the programming operation of FIG. 6 is performed again. For this programming operation, the programming voltage Vpgm is increased by the increment ΔISPP.

FIG. 8 is a timing diagram for describing another embodiment of a programming method of the non-volatile memory device 500 of FIG. 5. As in the programming method of FIG. 6 on the memory cell MT1, described in conjunction with the non-volatile memory device 500 of FIG. 5, the programming method of FIG. 8 also assumes that information about the state in which each of the memory cells MT0-MTn-1 is programmed according to LSB programming operations and LSB data read operations is known. That is to say, it is assumed that the memory cell MT1 among the memory cells MT0-MTn-1 in the memory cell array 510 is a memory cell to be programmed, that the memory cell MT0 among the rest of the memory cells MT0 and MT2-MTn-1 is a memory cell to be programmed or that has been programmed with the fourth type of data (10) of the state “P3” of FIG. 1, and that the memory cells MT2-MTn-1 are memory cells to be programmed or that have been programmed to a state, which is not the state “P3”.

Referring to FIG. 8, in the MSB programming method on the memory cell MT1, at a bit line precharge time T1, a power voltage VDD is applied to the string selection line SSL, and a first precharge voltage Vprch1 is applied to the bit line BL0 coupled to the program inhibit string CS0. The ground voltage VSS is also applied to the bit line BL1 coupled to the programming string CS1, and the power voltage VDD as a second precharge voltage Vprch2 is applied to the bit line BL[2:n-1] coupled to the program inhibit strings CS[2:n-1]. Accordingly the voltage of the channel CH0 of the memory cell MT0 is boosted by the first precharge voltage Vprch1 applied to the bit line BL0, to about a voltage level (Vprch1−Vth) equal to a difference between the first precharge voltage Vprch1 and the threshold voltage (Vth) of the string selection transistor SST (6). The voltage of the channel CH[2:n-1] of the memory cell MT[2:n-1] is boosted by the second precharge voltage Vprch2 applied to the bit line BL[2:n-1], about to a voltage level (Vprch2−Vth), equal to a difference between the second precharge voltage Vprch2 and the threshold voltage (Vth) of the string selection transistor SST (7).

The reason that the first precharge voltage Vprch1 that is lower than the power voltage VDD is applied to the bit line BL0 of the program inhibit string CS0 is for inducing less coupling the voltage of the memory cell channel CH0 voltage to the memory cell MT1 based on the information about that the memory cell MT0 is programmed with the fourth type of data (10) of the state “P3”. Though the voltage of the memory cell channel CH1 is lowered, the memory cell MT1 is still programmed in the state “P3” in which the voltage level is equal to or higher than a validation voltage, and thus, programming on the memory cell MT1 may not be disturbed by the programming voltage Vpgm applied to the word line WL2.

At a pass voltage applying time P2, the pass voltage Vpass generated by the voltage generator 530 is applied to the word lines WL[0:m-1], and, the voltage levels of the memory cell channel CH0 and the channel CH[2:n-1] of the memory cell MT[2:n-1] increase by being coupled with the pass voltage Vpass applied to the word lines WL[0:m-1] (8).

At a programming voltage applying time P3, the programming voltage Vpgm generated by the voltage generator 530 is applied to the selected word line WL2. The pass voltage Vpass is applied to the rest of the word lines WL0, WL1, WL[3:m-1]). The voltage levels of the memory cell channel CH0 and the channel CH[2:n-1] of the memory cell MT[2:n-1] increase by being coupled with the programming voltage Vpgm applied to the word line WL2 (9).

After the MSB programming operation on the memory cell MT1 is completed, a programming validation operation is executed. If the programming on the memory cell MT1 is validated as “pass” in the validation operation, the programming operation is terminated. Otherwise, if the programming on the memory cell MT1 is validated as “failure”, the programming operation of FIG. 6 performed again. For this programming operation, the programming voltage Vpgm is increased by the increment ΔISPP.

As described above with reference to FIG. 7, according to the programming method of FIG. 8, the voltage of the memory cell channel CH0 is lower than the voltage of the memory cell channel CH2. Thus, the voltage of the memory cell channel CH0 is less coupled to the floating gate FG of the memory cell MT1 than the voltage of the memory cell channel CH2 does. Thus, an ISPP error is less likely to occur in the memory cell MT1.

Thus, as described above, with respect to FIGS. 6 and 8, a method of programming a nonvolatile memory array (e.g., 510) having a plurality of strings of nonvolatile memory cells (CS0, CS1, CSn-1) therein electrically coupled to respective bit lines (BL0, BL1, BLn-1) may include applying a monotonically increasing sequence of a word line reference voltage, a first pass voltage greater than the word line reference voltage and a program voltage greater than the first pass voltage (see, e.g., Vss, Vpass1/Vpass2 and Vpgm) to a selected word line (e.g., WL2) in the nonvolatile memory array during the programming time interval illustrated by FIGS. 6 and 8. This sequence of steps is performed concurrently with driving a selected bit line (e.g., BL1) with a first voltage (e.g., Vss) that supports programming of a nonvolatile memory cell in a first string of nonvolatile memory cells (CS1) that is electrically coupled to the selected word line WL2. A step is also performed to drive at least a first unselected bit line (e.g., BL[2:n-1]) in the nonvolatile memory array with a first monotonically increasing sequence of a bit line reference voltage (e.g., Vss) and a first precharge voltage (Vprch in FIG. 6 or Vprch2 in FIG. 8) greater than the bit line reference voltage during the programming time interval. Likewise, a step is performed to drive a second unselected bit line (e.g., BL0) in the nonvolatile memory array with a second monotonically increasing sequence of the bit line reference voltage and a second precharge voltage (Vprch in FIG. 6 or Vprch1 in FIG. 8) greater than the bit line reference voltage during the programming time interval. This second monotonically increasing sequence includes a transition from the reference voltage to the second precharge voltage that occurs either later in time relative to a corresponding transition in the first monotonically increasing sequence (as shown by FIG. 6) or includes a smaller voltage increase relative to a transition from the reference voltage to the first precharge voltage (i.e., Vprch1<Vprch2, as shown by FIG. 8).

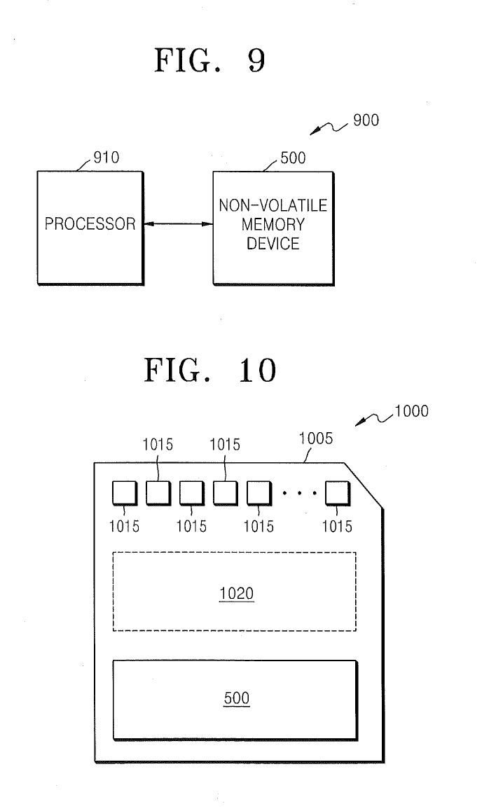

FIG. 9 illustrates a memory system 900 including at least one non-volatile memory device 500 that is programmed according to at least one embodiment of the programming method. Referring to FIG. 9, the memory system 900 includes a processor 910 connected to the non-volatile memory device 500 of FIG. 5. The memory system 900 may include separate integrated circuits in which the processor 910 and the non-volatile memory device 500 are respectively integrated, or may include one integrated circuit in which the processor 910 and the non-volatile memory device 500 are both integrated. The processor 910 may be a microprocessor, a memory controller, any other type of control circuit such as Application-Specific Integrated Circuit ASIC, or the like.

The processor 910 may include components, such as a random access memory (RAM), a processing unit, a host interface, and a memory interface. The RAM may be used as an operation memory of the processing unit. The processing unit may control the overall operation of the processor 910. The host interface may include a protocol for data communication between a host and the processor 910. For example, the processor 910 may be configured to externally communicate with an external device (host) via one of a variety of interface protocols, such as USB, MMC, PCI-E, ATA (Advanced Technology Attachment), Serial-ATA, Parallel-ATA, SCSI, ESDI, and IDE (International Drive Electronics). The memory interface may interface with the non-volatile memory device 500. The processor 910 may further include an error correction block. The error correction block may detect and correct an error in data read from the non-volatile memory device 500.

FIG. 10 illustrates a memory module 1000 including at least one non-volatile memory device 500 that is programmed according to at least one embodiment of the programming method. Referring to FIG. 10, the memory module 1000 may be a memory card. However, the concepts described with reference to the memory module 1000 are applicable to other types of mobile or portable memories (for example, a USB flash driver), and fall within the category of the memory module described herein.

The memory module 1000 includes a housing 1005 enclosing each of the at least one of the non-volatile memory devices 500. However, the housing 1006 is not essential in every device or device application. The non-volatile memory device 500 may perform a programming operation by applying a precharge voltage to a program inhibit cell at a different time according to the threshold voltage of the program inhibit cell or by applying a different level of precharge voltage to a program inhibit cell according to the threshold voltage of the program inhibit cell. The housing 1005 includes at least one connector 1015 for communication with a host device. Examples of the host device include a digital camera, a digital recoding and playback device, a PDA, a PC, a memory card reader, an interface hub, and the like. The at least one connector 1015 may have a standard interface. For example, if the memory card is a USB flash driver, the at least one connector 1015 may be a USB Type-A male connector. The at least one connector 1015 provides an interface for transferring a control signal, an address signal and/or a data signal between the memory module 1000 and a host device including a receptor compatible with the at least one connector 1015.

Optionally, the memory module 1000 may include an additional circuit 1020, which may include at least one integrated circuit and/or a separate device. The additional circuit 1020 may include a control circuit that controls access to the non-volatile memory device 500 and provides a translation layer between an external host and the non-volatile memory device 500. For example, the additional circuit 1020 may be a memory controller. The at least one connector 1015 may not correspond one-to-one to connection parts of the at least one non-volatile memory device 500. In this regard, the memory controller 1020 may selectively connect the at least one connector 1015 to the I/O connection ports of the at least one non-volatile memory device 1500 in order for an appropriate I/O connection part to receive an appropriate signal at an appropriate time or in order for an appropriate connector 1015 to provide an appropriate signal at an appropriate time. Likewise, a communication protocol between a host and the memory module 1000 may differ from that allowing access to the at least one non-volatile memory device 1500. In order to achieve appropriate access to the at least one non-volatile memory device 500, the memory controller 1020 may transform command sequences received from the host into appropriate command sequences. Furthermore, signal voltage levels, in addition to the command sequences, may vary.

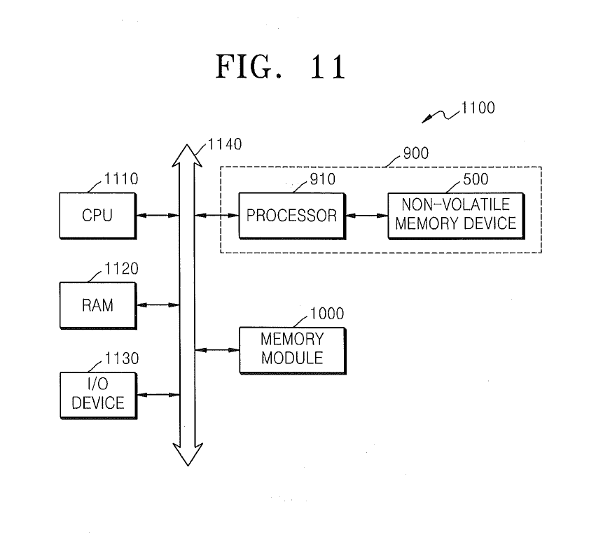

FIG. 11 illustrates a computer system 1100 including the memory system 900 of FIG. 9 or the memory module 1000 of FIG. 10. Referring to FIG. 11, the computer system 1100 includes a central processing unit (CPU) 1110, a RAM 1120, an I/O device 1130, and the memory system 900. The computer system 1100 may include the memory module 1000 of FIG. 9, instead of the memory system 900. The computer system 1100 is connected to the CPU 1110, the RAM 1120, and the I/O device 1130 via a system bus 1140. Data provided via the I/O device 1130 or data processed by the CPU 1110 are stored in the memory system 900 or the memory module 1000. The memory system 900 includes a processor 910 connected to the non-volatile memory device 500. The memory module 1000 includes a memory controller 1020 (see FIG. 10) and the non-volatile memory device 500. The non-volatile memory device 500 may perform a programming operation by applying a precharge voltage to a program inhibit cell at a different time according to the threshold voltage of the program inhibit cell or by applying a different level of precharge voltage to a program inhibit cell according to the threshold voltage of the program inhibit cell. If the memory system 900 is installed in a semiconductor disc device, for example, a solid state disc (SSD), the booting speed of the computer system 1100 may be markedly increased. The memory module 1000 may be a mobile or portable memory.

While the inventive concept has been particularly shown and described with reference to exemplary embodiments thereof, it will be understood that various changes in form and details may be made therein without departing from the spirit and scope of the following claims.

1. A method of programming a nonvolatile memory array having a plurality of strings of nonvolatile memory cells therein electrically coupled to respective bit lines, comprising:
applying a monotonically increasing sequence of a word line reference voltage, a first pass voltage greater than the word line reference voltage and a program voltage greater than the first pass voltage to a selected word line in the nonvolatile memory array during a programming time interval, while concurrently driving a selected bit line with a first voltage that supports programming of a nonvolatile memory cell in a first string of nonvolatile memory cells that is electrically coupled to the selected word line;
driving at least a first unselected bit line in the nonvolatile memory array with a first monotonically increasing sequence of a bit line reference voltage and a first precharge voltage greater than the bit line reference voltage during the programming time interval; and
driving a second unselected bit line in the nonvolatile memory array with a second monotonically increasing sequence of the bit line reference voltage and a second precharge voltage greater than the bit line reference voltage during the programming time interval, said second monotonically increasing sequence including a transition from the reference voltage to the second precharge voltage that occurs either later in time relative to a corresponding transition in the first monotonically increasing sequence or includes a smaller voltage increase relative to a transition from the reference voltage to the first precharge voltage.

2. The method of claim 1, further comprising applying a monotonically increasing sequence of the word line reference voltage and the first pass voltage to an unselected word line in the nonvolatile memory array during the programming time interval.

3. A method of programming a nonvolatile memory array having a plurality of strings of nonvolatile memory cells therein electrically coupled to respective bit lines, comprising:
applying a monotonically increasing sequence of a word line reference voltage, a first pass voltage greater than the word line reference voltage, a second pass voltage greater than the first pass voltage and a program voltage greater than the second pass voltage to a selected word line in the nonvolatile memory array during a programming time interval, while concurrently driving a selected bit line with a first voltage that supports programming of a nonvolatile memory cell in a first string of nonvolatile memory cells that is electrically coupled to the selected word line;
driving at least a first unselected bit line in the nonvolatile memory array with a first monotonically increasing sequence of a bit line reference voltage and a precharge voltage greater than the bit line reference voltage during the programming time interval; and
driving a second unselected bit line in the nonvolatile memory array with a second monotonically increasing sequence of the bit line reference voltage and the precharge voltage during the programming time interval, said second monotonically increasing sequence including a second transition from the reference voltage to the precharge voltage that occurs later in time relative to a corresponding transition in the first monotonically increasing sequence.

4. The method of claim 3, further comprising applying a monotonically increasing sequence of the word line reference voltage, the first pass voltage and the second pass voltage to an unselected word line in the nonvolatile memory array during the programming time interval.

5. A programming method of a non-volatile memory device, the method comprising:
applying a precharge voltage to a bit line of a first program inhibit cell;
sequentially applying a first pass voltage, a second pass voltage, and a programming voltage to a word line of a programming memory cell; and
applying the precharge voltage to a bit line of a second program inhibit cell before the second pass voltage is applied to the word line of the programming memory cell.

6. The programming method of claim 5, wherein a threshold voltage of the second program inhibit cell is higher than that of the first program inhibit cell.

7. The programming method of claim 5, wherein the non-volatile memory device comprises a NAND flash memory device including multi-level cells.

8.-24. (canceled)
